(19) United States
(12) Patent Application Publication
(10) Pub. No.: US 2024/0282826 A1
(43) Pub. Date: Aug. 22, 2024

(54) NITRIDE SEMICONDUCTOR DEVICE

(71) Applicant: ROHM CO., LTD., Kyoto-shi (JP)

(72) Inventor: Hirotaka OTAKE, Kyoto-shi (JP)

(73) Assignee: ROHM CO., LTD., Kyoto-shi (JP)

(21) Appl. No.: 18/434,940

(22) Filed: Feb. 7, 2024

(30) Foreign Application Priority Data
Feb. 16, 2023 (JP) 2023-022511

(51) Int. Cl. H01L 29/20; H01L 29/423; H01L 29/778

(52) U.S. Cl. CPC H01L 29/2003; H01L 29/42356; H01L 29/7787

(57) ABSTRACT

The present disclosure provides a nitride semiconductor device. The nitride semiconductor device includes an electron travelling layer, an electron supply layer, a gate layer, a gate electrode, a source electrode, a drain electrode and a passivation layer. The gate layer includes a gate layer side surface located at an end portion of a side of the source electrode along a first direction, which is a direction in which the gate layer, the source electrode and the drain electrode are arranged. The passivation layer includes a passivation first side surface facing the source electrode along the first direction. The nitride semiconductor device further includes a source insulator film that covers the gate layer side surface and the passivation first side surface. The source insulator film insulates the gate layer from the source electrode.

### CROSS-REFERENCE TO RELATED APPLICATION

This application is based upon and claims the benefit of priority from Japanese Patent Application No. 2023-022511, filed on Feb. 16, 2023, the entire contents of which are incorporated herein by reference.

### TECHNICAL FIELD

The present invention relates to a nitride semiconductor device.

### BACKGROUND

Currently, high electron mobility transistors (HEMTs) using Group III nitride semiconductors such as gallium nitride (GaN) (hereinafter sometimes simply referred to as “nitride semiconductors”) are being commercialized. HEMT uses two-dimensional electron gas (2DEG) formed near the semiconductor heterojunction interface as a conductive path (channel). Power devices using HEMTs are known to be capable of low on-resistance and high-speed/high-frequency operation compared to typical silicon (Si) power devices.

For example, the nitride semiconductor device described in Patent Document 1 includes an electron travelling layer composed of a gallium nitride (GaN) layer and an electron supply layer composed of an aluminum gallium nitride (AlGaN) layer. 2DEG is formed in the electron travelling layer near the heterojunction interface between the electron travelling layer and the electron supply layer. In addition, in the nitride semiconductor device of Patent Document 1, a gate layer (for example, a p-type GaN layer) containing acceptor-type impurities is provided at a position directly below the gate electrode on the electron travelling layer. In this structure, in the area directly below the gate layer, the gate layer will increase the band energy of the conduction band near the heterojunction interface between the electron travelling layer and the electron supply layer, so that the channel directly below the gate layer will disappear, thus achieving normal disconnection.

### PRIOR TECHNICAL LITERATURE

### Patent Documents

[Patent Document 1] Japanese Patent Application Publication No. 2017-73506

### BRIEF DESCRIPTION OF THE DRAWINGS

FIG. 1 is an exemplary schematic top view of a nitride semiconductor device.

FIG. 2 is a cross-sectional view taken along line 2-2 in FIG. 1.

FIG. 3 is an enlarged cross-sectional view of the periphery of the source electrode and the gate electrode in the nitride semiconductor device of FIG. 2.

FIG. 4 is a schematic cross-sectional view showing an exemplary manufacturing step of the nitride semiconductor device of FIG. 1.

FIG. 5 is a schematic cross-sectional view showing an exemplary manufacturing step subsequent to FIG. 4.

FIG. 6 is a schematic cross-sectional view showing an exemplary manufacturing step subsequent to FIG. 5.

FIG. 7 is a schematic cross-sectional view showing an exemplary manufacturing step subsequent to FIG. 6.

FIG. 8 is a schematic cross-sectional view showing an exemplary manufacturing step subsequent to FIG. 7.

FIG. 9 is a schematic cross-sectional view showing an exemplary manufacturing step subsequent to FIG. 8.

FIG. 10 is a schematic cross-sectional view showing an exemplary manufacturing step subsequent to FIG. 9.

FIG. 11 is a schematic cross-sectional view showing an exemplary manufacturing step subsequent to FIG. 10.

FIG. 12 is a schematic cross-sectional view showing an exemplary manufacturing step subsequent to FIG. 11.

FIG. 13 is a schematic cross-sectional view showing an exemplary manufacturing step subsequent to FIG. 12.

FIG. 14 is a schematic cross-sectional view showing an exemplary manufacturing step subsequent to FIG. 13.

FIG. 15 is a schematic cross-sectional view showing an exemplary manufacturing step subsequent to FIG. 14.

FIG. 16 is a schematic cross-sectional view showing an exemplary manufacturing step subsequent to FIG. 15.

FIG. 17 is a schematic cross-sectional view showing an exemplary manufacturing step subsequent to FIG. 16.

FIG. 18 is a schematic cross-sectional view showing an exemplary manufacturing step subsequent to FIG. 17.

FIG. 19 is a schematic cross-sectional view showing an exemplary manufacturing step subsequent to FIG. 18.

FIG. 20 is a schematic cross-sectional view showing an exemplary manufacturing step subsequent to FIG. 19.

FIG. 21 is a schematic cross-sectional view showing an exemplary manufacturing step subsequent to FIG. 20.

FIG. 22 is a schematic cross-sectional view showing an exemplary manufacturing step subsequent to FIG. 21.

FIG. 23 is a schematic cross-sectional view showing an exemplary manufacturing step subsequent to FIG. 22.

FIG. 24 is a schematic cross-sectional view showing an exemplary manufacturing step subsequent to FIG. 23.

FIG. 25 is a schematic cross-sectional view showing an exemplary manufacturing step subsequent to FIG. 24.

FIG. 26 is a schematic cross-sectional view showing an exemplary manufacturing step subsequent to FIG. 25.

### DETAILED DESCRIPTION OF THE EMBODIMENTS

Hereinafter, embodiments of the nitride semiconductor device disclosed herein will be illustrated with reference to the accompanying drawings.

In addition, in order to make the description simple and clear, the components shown in the drawings are not necessarily drawn on a fixed scale. Further, in order to facilitate understanding, hatching may be omitted in cross-sectional views. The drawings are merely used to illustrate the embodiments disclosed herein and should not be construed as limiting the invention disclosed herein.

The following detailed description includes devices, systems and methods that embody the exemplary embodiments disclosed herein. The detailed description is intended to be illustrative only, and is not intended to limit the embodiments disclosed herein or the application and use of such embodiments.

### [Schematic Structure of Nitride Semiconductor Device]

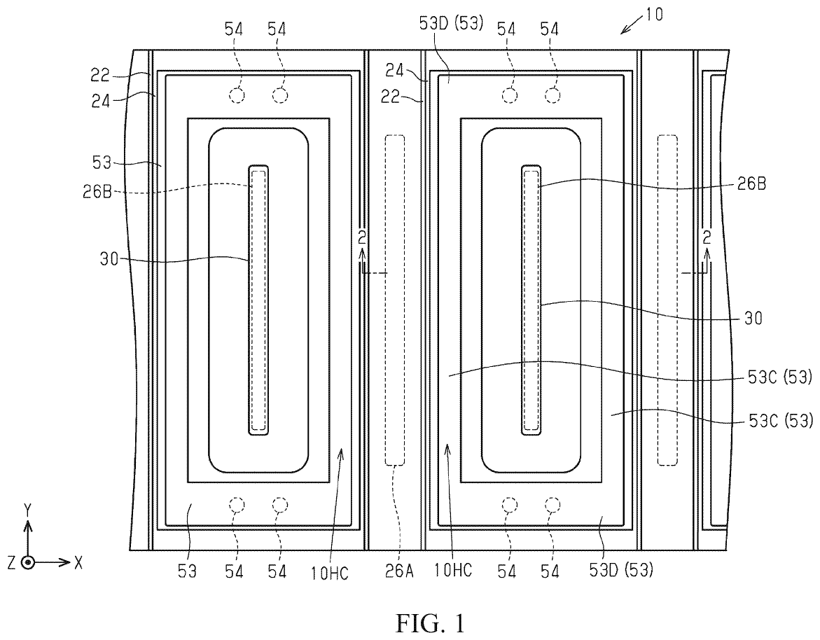

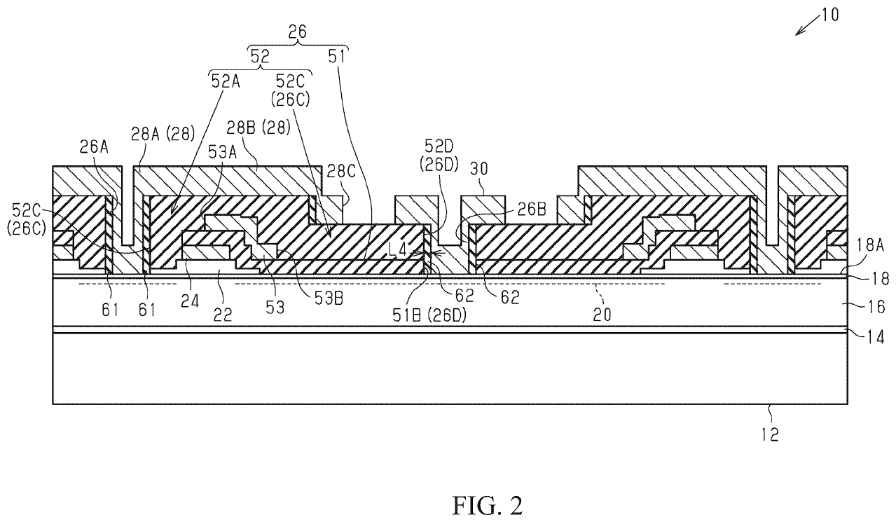

FIG. 1 is a schematic top view of an exemplary nitride semiconductor device 10 according to an embodiment. FIG. 2 is a schematic cross-sectional view of the nitride semiconductor device 10, taken along line 2-2 in FIG. 1. In one example, the nitride semiconductor device 10 may be a HEMT using GaN. Hereinafter, the cross-sectional structure of the nitride semiconductor device 10 will be described first with reference to FIG. 2, and then the planar structure of the nitride semiconductor device 10 will be described with reference to FIG. 1.

As shown in FIG. 2, the nitride semiconductor device 10 includes a semiconductor substrate 12, a buffer layer 14 formed on the semiconductor substrate 12, an electron travelling layer 16 formed on the buffer layer 14, and an electron supply layer 18 formed on the electron travelling layer 16.

The semiconductor substrate 12 may be formed of silicon (Si), silicon carbide (SiC), GaN, sapphire, or other substrate materials. In one example, the semiconductor substrate 12 may be a Si substrate. The thickness of the semiconductor substrate 12 may be, for example, 200 μm or more and 1500 μm or less. The Z-axis direction of the mutually orthogonal XYZ axes shown in FIGS. 1 and 2 is the thickness direction of the semiconductor substrate 12. In addition, the term “top view” used in this specification means that the nitride semiconductor device 10 is viewed from above along the Z-axis direction unless otherwise specified.

The buffer layer 14 may be located between the semiconductor substrate 12 and the electron travelling layer 16. In one example, the buffer layer 14 may be made of any material that can easily epitaxially grow the electron travelling layer 16. The buffer layer 14 may include one or more nitride semiconductor layers.

In one example, the buffer layer 14 may include at least one of an aluminum nitride (AlN) layer, an aluminum gallium nitride (AlGaN) layer, and a gate-type AlGaN layer with different aluminum (Al) combinations. For example, the buffer layer 14 may be composed of a single AlN layer, a single AlGaN layer, a layer with an AlGaN/GaN superlattice structure, a layer with an AlN/AlGaN superlattice structure, or a layer with an AlN/GaN superlattice structure. In addition, in order to suppress the leakage current in the buffer layer 14, impurities may be introduced into a portion of the buffer layer 14 to make the buffer layer 14 semi-insulating. In this case, the impurity may be carbon (C) or iron (Fe), for example, and the concentration of the impurity may be set to 4×10¹⁶ cm⁻³ or more, for example.

The electron travelling layer 16 is composed of a nitride semiconductor. The electron travelling layer 16 is, for example, a GaN layer. The thickness of the electron travelling layer 16 is, for example, 0.5 μm or more and 2 μm or less. In addition, in order to suppress the leakage current in the electron travelling layer 16, impurities may be introduced into a portion of the electron travelling layer 16 to make the region other than the surface layer region of the electron travelling layer 16 semi-insulating. In this case, the impurity is C, for example, and the peak concentration of the impurity in the electron travelling layer 16 is, for example, 1×10¹⁹ cm⁻³ or more.

The electron supply layer 18 is composed of a nitride semiconductor having a larger band gap than the electron travelling layer 16. The electron supply layer 18 is an AlGaN layer, for example. In this case, the more the Al component, the larger the band gap. Therefore, the electron supply layer 18 which is an AlGaN layer has a larger band gap than the electron travelling layer 16 which is a GaN layer. In one example, the electron supply layer 18 is composed of AlₓGa₁₋ₓN, where x is 0.1<x<0.4, and more preferably 0.2<x<0.3. The thickness of the electron supply layer 18 is, for example, 5 nm or more and 20 nm or less.

The electron travelling layer 16 and the electron supply layer 18 are composed of nitride semiconductors having different lattice constants from each other. Therefore, the nitride semiconductor (e.g., GaN) constituting the electron travelling layer 16 and the nitride semiconductor (e.g., AlGaN) constituting the electron supply layer 18 form a lattice-mismatched heterojunction. The energy level of the conduction band of the electron travelling layer 16 near the heterojunction interface will become lower than the Fermi level due to the spontaneous polarization of the electron travelling layer 16 and the electron supply layer 18 and the piezoelectric polarization induced by the stress on the electron supply layer 18 near the heterojunction interface. Therefore, in the electron travelling layer 16 at a position close to the heterojunction interface between the electron travelling layer 16 and the electron supply layer 18 (for example, within a range of about a few nanometers from the interface), there will be diffusion of two-dimensional electron gas (2DEG) 20.

The nitride semiconductor device 10 further includes a gate layer 22 formed on the electron supply layer 18, a gate electrode 24 formed on the gate layer 22, and a passivation layer 26. The passivation layer 26 is formed above the electron supply layer 18, the gate layer 22, and the gate electrode 24, and includes a first opening 26A and a second opening 26B. In addition, the nitride semiconductor device 10 further includes a source electrode 28 connected to the electron supply layer 18 via the first opening 26A, and a drain electrode 30 connected to the electron supply layer 18 via the second opening 26B.

The gate layer 22 is located between the first opening 26A and the second opening 26B of the passivation layer 26 and is separated from the first opening 26A and the second opening 26B respectively. The gate layer 22 is located closer to the first opening 26A than the second opening 26B. The detailed structure of the gate layer 22 will be described below.

The gate layer 22 is composed of a nitride semiconductor that has a smaller band gap than the electron supply layer 18 and contains acceptor-type impurities. The gate layer 22 may be made of any material having a smaller band gap than the electron supply layer 18 which is an AlGaN layer, for example. In one example, the gate layer 22 is a GaN layer doped with acceptor-type impurities (p-type GaN layer). The acceptor-type impurities may include at least one of zinc (Zn), magnesium (Mg), and C. The maximum concentration of the acceptor-type impurities in the gate layer 22 is, for example, 1×10¹⁸ cm⁻³ or more and 1×10²⁰ cm⁻³ or less.

By including the acceptor-type impurity in the gate layer 22 as described above, the energy levels of the electron travelling layer 16 and the electron supply layer 18 are raised. Therefore, in the region directly below the gate layer 22, the energy level of the conduction band of the electron travelling layer 16 near the heterojunction interface between the electron travelling layer 16 and the electron supply layer 18 becomes approximately the same as the Fermi level, or larger than the Fermi level. Therefore, when voltage is not applied to the gate electrode 24 (zero bias), 2DEG 20 is not formed in the region directly below the gate layer 22 in the electron travelling layer 16. 2DEG 20 will be formed in the region other than the region directly below the gate layer 22 in the electron travelling layer 16.

In this way, due to the presence of the gate layer 22 doped with the acceptor-type impurities, the 2DEG 20 in the region directly below the gate layer 22 is destroyed. As a result, the normally-off operation of the transistor is achieved. If an appropriate turn-on voltage is applied to the gate electrode 24, a channel composed of 2DEG 20 will be formed in the region directly below the gate electrode 24 in the electron travelling layer 16, so that the source-drain conduction occurs.

The gate electrode 24 is composed of one or more metal layers. In one example, the gate electrode 24 is a titanium nitride (TiN) layer. Alternatively, the gate electrode 24 may be composed of a first metal layer and a second metal layer laminated on the first metal layer, the first metal layer is made of a material containing Ti, and the second metal layer is made of a material containing TiN. The gate electrode 24 may form a Schottky junction with the gate layer 22. The gate electrode 24 may be formed in a smaller area than the gate layer 22 in a top view. The thickness of the gate electrode 24 is, for example, 50 nm or more and 200 nm or less.

The passivation layer 26 is formed on the electron supply layer 18. It can also be said that the passivation layer 26 covers the electron supply layer 18. The passivation layer 26 may be made of, for example, a material including any one of silicon nitride (SiN), silicon dioxide (SiO₂), silicon oxynitride (SiON), aluminum oxide (Al₂O₃), AlN, and aluminum oxynitride (AlON).

The thickness of the passivation layer 26 is greater than the thickness of the electron supply layer 18. The thickness of the passivation layer 26 is, for example, 300 nm or more and 1,000 nm or less. In addition, the thickness of the passivation layer 26 can be changed arbitrarily. The detailed structure of the passivation layer 26 will be described below.

The source electrode 28 and the drain electrode 30 are arranged on the upper surface of the electron supply layer 18 with the gate layer 22 interposed therebetween. The source electrode 28 and the drain electrode 30 may be composed of one or more metal layers. For example, the source electrode 28 and the drain electrode 30 may be composed of a combination of two or more metal layers selected from the group consisting of a Ti layer, a TiN layer, an Al layer, an AlSiCu layer, an AlCu layer, and the like. At least a portion of the source electrode 28 is filled in the first opening 26A, and is in ohmic contact with the 2DEG 20 directly below the electron supply layer 18 via the first opening 26A. Similarly, at least a portion of the drain electrode 30 is filled in the second opening 26B, and is in ohmic contact with the 2DEG 20 directly below the electron supply layer 18 via the second opening 26B.

In one example, the source electrode 28 may include a source contact portion 28A filled in the first opening 26A, and a source field plate portion 28B formed on the passivation layer 26. The source field plate portion 28B is continuous with the source contact portion 28A and is integrally formed with the source contact portion 28A. The source field plate portion 28B includes an end portion 28C located between the second opening 26B and the gate layer 22 in a top view. The source field plate portion 28B is separated from the drain electrode 30. The source field plate portion 28B functions as follows: when a drain voltage is applied to the drain electrode 30 in a zero-bias state in which a gate voltage is not applied to the gate electrode 24, the electric field concentration near an end of the gate electrode 24 and near an end of the gate layer 22 is relaxed.

### [Detailed Structure of Gate Layer]

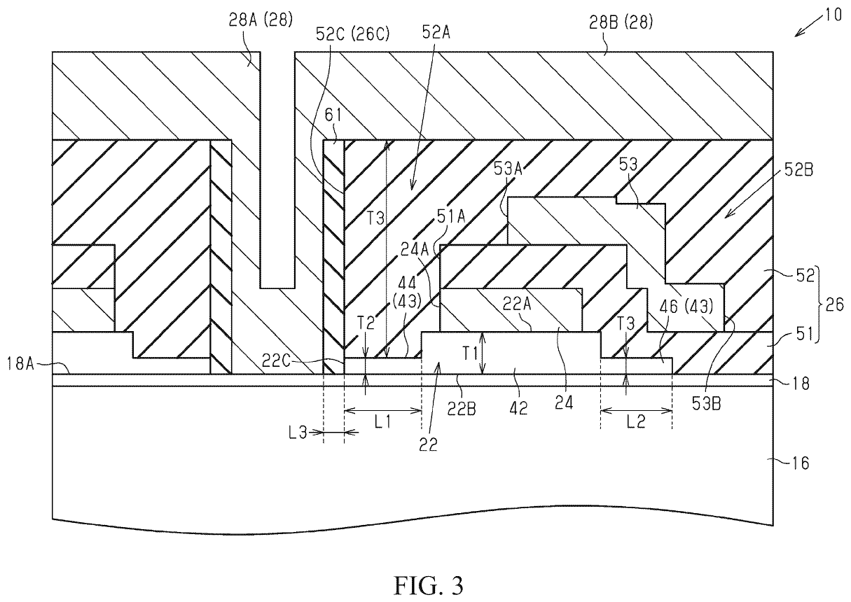

The gate layer 22 may have a stepped structure. Hereinafter, the details of the gate layer 22 having the stepped structure will be described with reference to FIG. 3. FIG. 3 is an enlarged cross-sectional view of the periphery of the source electrode 28 and the gate electrode 24 in the nitride semiconductor device 10 of FIG. 2. Furthermore, 2DEG 20 is omitted from FIG. 3.

The gate layer 22 includes a ridge portion 42 and extension portions 43 extending in opposite directions from both sides of the ridge portion 42. The ridge portion 42 and the extension portion 43 form a stepped structure of the gate layer 22.

The ridge portion 42 corresponds to a relatively thick portion of the gate layer 22. The gate electrode 24 contacts the ridge portion 42. The ridge portion 42 may have a rectangular shape or a trapezoidal shape in a cross-section along the XZ plane of FIG. 3. The ridge portion 42 may have a thickness of, for example, 100 nm or more and 200 nm or less. The thickness T1 of the ridge portion 42 refers to the distance from the upper surface to the lower surface of the ridge portion 42 (from the upper surface 22A of the gate layer 22 on which the gate electrode 24 is formed to the lower surface 22B of the gate layer 22 in contact with the electron supply layer 18). The thickness T1 of the ridge portion 42 (the gate layer 22) can be determined taking into consideration of various parameters such as the gate withstand voltage.

The extension portion 43 includes a source-side extension portion 44 and a drain-side extension portion 46. The source-side extension portion 44 extends from the ridge portion 42 toward the first opening 26A of the passivation layer 26. The drain-side extension portion 46 extends from the ridge portion 42 toward the second opening 26B of the passivation layer 26 (referring to FIG. 2). The source-side extension portion 44 and the drain-side extension portion 46 may have the same length, or may have different lengths.

The source-side extension portion 44 may have a thickness T2 of 5 nm or more and 30 nm or less, for example. The source-side extension portion 44 may have a first direction length L1 of, for example, 100 nm or more in the direction from the ridge portion 42 toward the first opening 26A. The first direction length L1 of the source-side extension portion 44 is, for example, 200 nm or more and 300 nm or less. The drain-side extension portion 46 may have a thickness T3 of 5 nm or more and 30 nm or less, for example. The drain-side extension portion 46 may have a first direction length L2 of, for example, 200 nm or more and 600 nm or less in the direction from the ridge portion 42 toward the second opening 26B. The thickness T2 of the source-side extension portion 44 and the thickness T3 of the drain-side extension portion 46 are equal to each other. Here, if the difference between the thickness T2 of the source-side extension portion 44 and the thickness T3 of the drain-side extension portion 46 is, for example, within 10% of the thickness of the source-side extension portion 44, then it can be said that the thickness T2 of the source-side extension portion 44 and the thickness T3 of the drain-side extension portion 46 are equal to each other.

The gate layer 22 has an upper surface 22A and a lower surface 22B. The lower surface 22B is the surface of the gate layer 22 facing the upper surface 18A of the electron supply layer 18, and the upper surface 22A is the surface of the gate layer 22 located on the opposite side to the lower surface 22B. The upper surface 22A of the gate layer 22 having the stepped structure represents the upper surface of the ridge portion 42. The lower surface 22B of the gate layer 22 having the stepped structure represents a surface including the lower surface of the ridge portion 42, the lower surface of the source-side extension portion 44, and the lower surface of the drain-side extension portion 46.

In addition, the cross-sectional shape of the gate layer 22 is not limited to a shape having a stepped structure. For example, the gate layer 22 may have a rectangular, trapezoidal or ridge-shaped cross-section on the XZ plane in FIG. 1.

### [Detailed Structure of Passivation Layer]

As shown in FIG. 2, an example of the passivation layer 26 includes at least a first passivation layer 51 formed above the electron supply layer 18 and a second passivation layer 52 formed above the first passivation layer 51. In addition, the field plate electrode 53 is embedded between the first passivation layer 51 and the second passivation layer 52 of the passivation layer 26.

An example of the first passivation layer 51 is formed on the gate electrode 24, a region of the gate layer 22 located closer to the drain electrode 30 than the gate electrode 24, and a region of the electron supply layer 18 located between the gate layer 22 and the drain electrode 30. In other words, the first passivation layer 51 is in contact with and covers the upper surfaces of the gate electrode 24, the region of the gate layer 22, and the region of the electron supply layer 18.

As shown in FIG. 3, the first passivation layer 51 has a first side surface 51A located at an end on the source electrode 28 side in the X direction, that is, the direction in which the source electrode 28, the gate electrode 24 and the drain electrode 30 are arranged (hereinafter referred to as the first direction). The first side surface 51A of the first passivation layer 51 is located above the electrode side surface 24A that is located at an end of the gate electrode 24 on the source electrode 28 side. The first side surface 51A and the electrode side surface 24A are on the same plane and form a continuous side surface. In addition, as shown in FIG. 2, the first passivation layer 51 has a second side surface 51B located at an end on the drain electrode 30 side in the first direction.

In addition, the first passivation layer 51 only needs to be formed at least partially on a region of the electron supply layer 18 closer to the drain electrode than the gate layer 22. In addition, when the field plate electrode 53 is provided, the first passivation layer 51 has a portion located between the field plate electrode 53 and the gate layer 22 and between the field plate electrode 53 and the gate electrode 24.

The first passivation layer 51 has a thickness of, for example, 50 nm or more and 200 nm or less. The thickness of the first passivation layer 51 may be, for example, the thickness of the portion formed on the electron supply layer 18 or the thickness of the portion formed on the gate electrode 24 or the gate layer 22.

As shown in FIG. 2, an example of the second passivation layer 52 includes: a source side portion 52A formed on a portion of the gate layer 22 closer to the source electrode 28 than the gate electrode 24; and a drain side portion 52B formed on the first passivation layer 51. A field plate electrode 53 is formed between the first passivation layer 51 and the drain side portion 52B of the second passivation layer 52. Details of the field plate electrode 53 will be described below.

As shown in FIG. 3, the source side portion 52A of the second passivation layer 52 has a first side surface 52C located at an end on the source electrode 28 side in the first direction. The first side surface 52C of the second passivation layer 52 is located above the gate layer side surface 22C, which is located at the end of the gate layer 22 on the source electrode 28 side. In the example shown in FIG. 3, the gate layer side surface 22C is the front end surface of the source-side extension portion 44. The first side surface 52C of the second passivation layer 52 and the gate layer side surface 22C are on the same plane, and form a continuous side surface. In addition, the source side portion 52A of the second passivation layer 52 is in contact with the electrode side surface 24A of the gate electrode 24 and the first side surface 51A of the first passivation layer 51.

As shown in FIG. 2, the drain-side portion 52B of the second passivation layer 52 has a second side surface 52D located at an end on the drain electrode 30 side in the first direction. The second side surface 52D of the second passivation layer 52 is located above the second side surface 51B of the first passivation layer 51. The second side surface 52D of the second passivation layer 52 and the second side surface 51B of the first passivation layer 51 are on the same plane and form a continuous side surface.

Herein, the passivation layer 26 has a passivation first side surface 26C facing the source electrode 28 in the first direction, and a passivation second side surface 26D facing the drain electrode 30. The passivation first side surface 26C is formed from the first side surface 52C of the second passivation layer 52. The passivation second side surface 26D is formed from the second side surface 51B of the first passivation layer 51 and the second side surface 52D of the second passivation layer 52.

In addition, it can also be said that the second passivation layer 52 is a portion of the passivation layer 26 other than the first passivation layer 51. The formation range of the second passivation layer 52 can be changed according to the formation range of the first passivation layer 51.

The second passivation layer 52 is formed thicker than the first passivation layer 51, for example. The thickness of the second passivation layer 52 is, for example, the thickness T3 of the portion forming the first side surface 52C in the source side portion 52A. The thickness T3 of the second passivation layer 52 is, for example, 500 nm or more and 1,500 nm or less. In addition, the thickness T3 of the second passivation layer 52 can also be said to be the thickness on the first side surface 52C of the second passivation layer 52.

Each of the first passivation layer 51 and the second passivation layer 52 may be made of the material comprising any one of silicon nitride (SiN), silicon dioxide (SiO₂), silicon oxynitride (SiON), aluminum oxide (Al₂O₃), AlN, and aluminum oxynitride (AlON), for example. The first passivation layer 51 and the second passivation layer 52 may be made of the same material. In one example, the first passivation layer 51 and the second passivation layer 52 are both silicon nitride (SiN) layers.

In addition, the first passivation layer 51 and the second passivation layer 52 may be made of different materials. In one example, the first passivation layer 51 is a silicon nitride (SiN) layer, and the second passivation layer 52 is a silicon dioxide (SiO₂) layer. By setting the first passivation layer 51 covering the electron supply layer 18 as a silicon nitride (SiN) layer, the surface of the electron supply layer 18 is protected, thereby enabling the effect of reducing trap energy level. In addition, by setting the second passivation layer 52 that forms the passivation first side surface 26C facing the source electrode 28 as a silicon dioxide (SiO₂) layer, even if the source electrode 28 is sintered, it is also possible to more stably insulate the gate electrode 24 from the source electrode 28.

Next, the field plate electrode 53 will be described. As shown in FIG. 2, the field plate electrode 53 is separated from the drain electrode 30. The field plate electrode 53 functions as follows: when a drain voltage is applied to the drain electrode 30 in a zero-bias state in which a gate voltage is not applied to the gate electrode 24, the electric field concentration near the end of the gate layer 22 is relaxed. In addition, the source field plate portion 28B of the source electrode 28 relaxes the electric field concentration when a relatively large voltage is applied, and the field plate electrode 53 relaxes the electric field concentration when a relatively small voltage is applied.

At least a portion of the field plate electrode 53 is formed between the gate layer 22 on the first passivation layer 51 and the drain electrode 30. The field plate electrode 53 is electrically connected to the source electrode 28, but this is not shown in FIG. 2. Details of the connection structure between the field plate electrode 53 and the source electrode 28 will be described below.

The field plate electrode 53 includes a first end portion 53A that is an end portion in the first direction, and a second end portion 53B located on the opposite side of the first end portion 53A. The first end portion 53A is an end portion of the field plate electrode 53 close to the source electrode 28. The second end 53B is an end of the field plate electrode 53 close to the drain electrode 30.

The second end portion 53B of the field plate electrode 53 is located on the first passivation layer 51 between the gate layer 22 and the drain electrode 30. The second end portion 53B is located, for example, between the gate layer 22 and the drain electrode 30 and close to the gate layer 22.

As shown in FIG. 3, an example of the first end portion 53A of the field plate electrode 53 is located above the gate electrode 24. In this case, the field plate electrode 53 has a portion that overlaps the gate electrode 24 with the first passivation layer 51 therebetween. As the area of the portion of the field plate electrode 53 overlapping the gate electrode 24 increases, the parasitic capacitance between the gate and the source increases. By increasing the parasitic capacitance between the gate and the source, self-starting is suppressed, and the operation of the nitride semiconductor device 10 becomes stable. Furthermore, in this case, the field plate electrode 53 covers the end of the gate layer 22 on the side close to the drain electrode 30 (the tip of the drain-side extension portion 46) with the first passivation layer 51 therebetween. As a result, the electric field concentration at the end of the gate layer 22 close to the drain electrode 30 can be alleviated.

In addition, the position of the first end portion 53A of the field plate electrode 53 can be changed as appropriate. For example, it may be located above a region of the gate layer 22 closer to the drain electrode 30 than the gate electrode 24 (for example, above the drain-side extension portion 46), or may be located on the first passivation layer 51 between the gate layer 22 and the drain electrode 30.

Herein, the positional relationship between the field plate electrode 53 and the source field plate portion 28B of the source electrode 28 will be described. As shown in FIG. 2, the source field plate portion 28B is formed above the second passivation layer 52. The end portion 28C of the source field plate portion 28B is located closer to the drain electrode 30 than the second end portion 53B of the source field plate electrode 53 in the first direction.

The source electrode 28 and the drain electrode 30 may be composed of a combination of two or more metal layers selected from the group consisting of a Ti layer, a TiN layer, an Al layer, an AlSiCu layer, an AlCu layer, and the like. The field plate electrode 53 may be composed of one or more metal layers. For example, the field plate electrode 53 is composed of a TiN layer or a combination of a Ti layer and a TiN layer. In addition, an example of the field plate electrode 53 may be made of the same material as one or both of the source electrode 28 and the drain electrode 30.

### [Peripheral Structure of Source Electrode and Gate Electrode]

As shown in FIG. 3, the nitride semiconductor device 10 includes a source insulator film 61 that insulates the source electrode 28 and the gate layer 22. The source insulator film 61 is formed between the source electrode 28 and the gate layer 22 and covers the gate layer side surface 22C of the gate layer 22. In addition, the source insulator film 61 is formed between the source electrode 28 and the passivation layer 26 and covers the passivation first side surface 26C of the passivation layer 26.

The source insulator film 61 is formed by self-alignment with respect to the side surface (sidewall) formed by the passivation first side surface 26C of the passivation layer 26 and the gate layer side surface 22C of the gate layer 22 of. In this way, the source insulator film 61 can be formed thin. The first direction length L3 of the source insulator film 61 is shorter than the first direction length L1 of the source side extension portion 44 of the gate layer 22. The first direction length L3 of the source insulator film 61 is less than 100 nm, for example.

The source insulator film 61 may be made of the material comprising, for example, any one of silicon nitride (SiN), silicon dioxide (SiO₂), silicon oxynitride (SiON), aluminum oxide (Al₂O₃), AlN, and aluminum oxynitride (AlON). In one example, the source insulator film 61 is a silicon dioxide (SiO₂) film. In addition, the source insulator film 61 may be made of the same material as the first passivation layer 51, or may be made of a different material from the first passivation layer 51. In addition, the source insulator film 61 may be made of the same material as the second passivation layer 52, or may be made of a different material from the second passivation layer 52. An example of the source insulator film 61 is composed of a material having higher insulation properties than the portion forming the passivation first side surface 26C, which is the second passivation layer 52.

### [Peripheral Structure of Drain Electrode]

As shown in FIG. 2, the nitride semiconductor device 10 further includes a drain insulator film 62. The drain insulator film 62 covers the passivation second side surface 26D of the passivation layer 26 and is insulated from the passivation second side surface 26D. The drain insulator film 62 is formed with respect to the passivation second side surface 26D of the passivation layer 26, i.e. the side surface (sidewall) formed by the second side surface 51B of the first passivation layer 51 and the second side surface 52D of the second passivation layer 52, through self-alignment. As a result, the drain insulator film 62 can be formed thin. The first direction length L4 of the drain insulator film 62 is less than 100 nm, for example. The first direction length L4 of the drain insulator film 62 may be the same as or different from the first direction length L1 of the source insulator film 61.

The drain insulator film 62 may be made of, for example, the material comprising any one of silicon nitride (SiN), silicon dioxide (SiO₂), silicon oxynitride (SiON), aluminum oxide (Al₂O₃), AlN, and aluminum oxynitride (AlON). In one example, the drain insulator film 62 is a silicon dioxide (SiO₂) film. In addition, the drain insulator film 62 may be made of the same material as the first passivation layer 51, or may be made of a different material from the first passivation layer 51. In addition, the drain insulator film 62 may be made of the same material as the second passivation layer 52, or may be made of a different material from the second passivation layer 52.

The drain insulator film 62 is, for example, interposed between the sites where a large electric field concentration occurs, i.e. between the end of the drain electrode 30 in the first direction and the passivation layer 26, thereby suppressing electrons from the drain electrode 30 from injection into the passivation layer 26. In this case, long-term stability of the electrical characteristics (for example, withstand voltage between the drain and source) of the nitride semiconductor device 10 can be achieved.

### [Planar Structure of Nitride Semiconductor Device]

Next, the planar structure of the nitride semiconductor device 10 will be described with reference to FIG. 1. In FIG. 1, the passivation layer 26 and the source electrode 28 are omitted, and the first opening 26A and the second opening 26B are drawn with dotted lines.

The nitride semiconductor device 10 includes, for example, a working region that contributes to transistor operation and a non-working region (not shown) that does not contribute to transistor operation. In one example, working regions and non-working regions are alternately arranged along the Y direction.

In the working region of the nitride semiconductor device 10, the source electrode 28 (referring to FIG. 2), the gate electrode 24, and the drain electrode 30 are arranged adjacent to each other in the X direction on the electron supply layer 18 (referring to FIG. 2). The combination of the source electrode 28, the gate electrode 24, and the drain electrode 30 adjacent in the X direction constitutes one HEMT cell 10HC. In the example of FIG. 1, two HEMT units 10HC are arranged along the X direction in the working region. In addition, more HEMT units 10HC can actually be configured in each working region.

As shown in FIG. 1, the field plate electrode 53 is formed in a ring shape surrounding the drain electrode 30 in a top view. The field plate electrode 53 has body portions 53C located between the source electrode 28 and the drain electrode 30 in a top view; and connection portions 53D located closer to one side and the other side of the Y direction than the drain electrode 30, connecting two adjacent body portions 53C to each other.

A bonding via 54 is formed in the second passivation layer 52 (not shown) located on the connection portion 53D of the field plate electrode 53. The bonding via 54 penetrates the second passivation layer 52 (not shown) and is connected to the source electrode 28 (the source field plate portion 28B). As a result, the field plate electrode 53 is electrically connected to the source electrode 28 through the bonding via 54.

### [Method for Manufacturing Nitride Semiconductor Device]

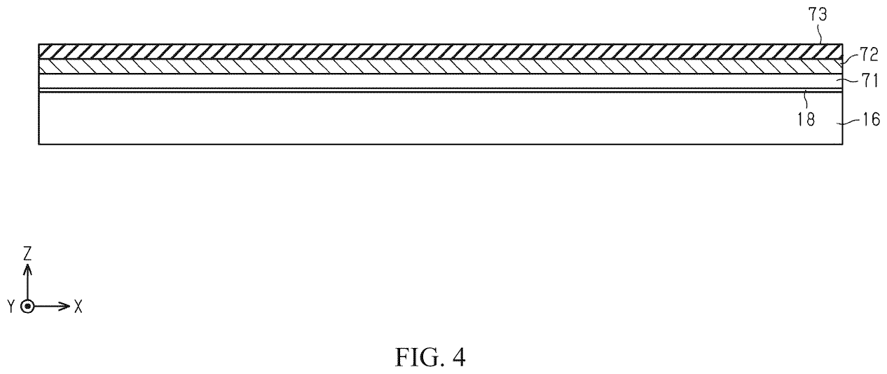

An exemplary method for manufacturing the nitride semiconductor device 10 will be described with reference to FIGS. 4 to 26. In addition, in FIGS. 4 to 26, the same components as those in FIG. 1 are denoted by the same reference numerals. In addition, in FIGS. 4 to 26, the semiconductor substrate 12 and the buffer layer 14 as shown in FIG. 2 are omitted for simple illustration.

The method for manufacturing the nitride semiconductor device 10 includes the following steps: forming an electron travelling layer 16; and forming an electron supply layer 18 on the electron travelling layer 16. The method for manufacturing the nitride semiconductor device 10 further includes the following steps: forming a gate layer 22 on the electron supply layer 18; forming a gate electrode 24 on the gate layer 22; and forming a passivation layer 26 on the electron supply layer 18, the gate layer 22, and the gate electrode 24. An example of the step of forming the passivation layer 26 includes: forming a first passivation layer 51 on the electron supply layer 18, the gate layer 22, and the gate electrode 24; forming a field plate electrode 53 on the first passivation layer 51; and forming a second passivation layer 52 on the first passivation layer 51 with the field plate electrode 53 interposed therebetween.

As shown in FIG. 4, the buffer layer 14 (not shown), the electron travelling layer 16, the electron supply layer 18 and a first nitride semiconductor layer 71 are sequentially formed on the semiconductor substrate 12 (not shown). The semiconductor substrate 12 is, for example, a Si substrate. The buffer layer 14, the electron travelling layer 16, the electron supply layer 18 and the first nitride semiconductor layer 71 are formed, for example, by epitaxial growth using a Metal Organic Chemical Vapor Deposition (MOCVD) method.

The buffer layer 14 (referring to FIG. 1) may be a multilayer buffer layer, for example, but the relevant illustration is omitted. The multilayer buffer layer may include an AlN layer (the first buffer layer) formed on the semiconductor substrate 12 and a gate-type AlGaN layer (the second buffer layer) formed on the AlN layer. In one example, the gate-type AlGaN layer is formed by sequentially laminating three AlGaN layers with Al components of 75%, 50%, and 25% respectively, starting from the side close to the AlN layer.

The electron travelling layer 16 is, for example, a GaN layer, and the electron supply layer 18 is, for example, an AlGaN layer. Therefore, the electron supply layer 18 is composed of a nitride semiconductor having a larger band gap than the electron travelling layer 16. The first nitride semiconductor layer 71 is a layer for forming the gate layer 22 and is, for example, a GaN layer containing Mg as an acceptor type impurity. The first nitride semiconductor layer 71 is formed by doping GaN with Mg while GaN is grown on the electron supply layer 18.

Next, a first electrode layer 72 is formed on the first nitride semiconductor layer 71, and a first protective layer 73 is formed on the first electrode layer 72. The first electrode layer 72 is a layer used to form the gate electrode 24, and is, for example, a TiN layer. The first electrode layer 72 is formed by a sputtering method, for example. The first protective layer 73 is, for example, a SiN layer. The first protective layer 73 is formed, for example, by a plasma-enhanced chemical vapor deposition (PECVD) method.

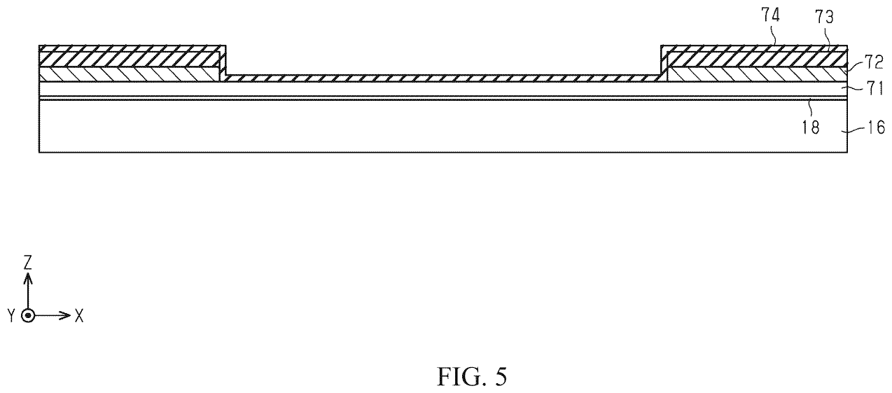

Next, as shown in FIG. 5, the first electrode layer 72 and the first protective layer 73 are selectively removed so as to expose a portion of the upper surface of the first nitride semiconductor layer 71, and then the second protective layer 74 covering the first electrode layer 72, the first protective layer 73 and the first nitride semiconductor layer 71 is formed. The first electrode layer 72 and the first protective layer 73 are selectively removed, for example, by performing photolithography and etching using a mask. The second protective layer 74 is, for example, a SiN layer. The second protective layer 74 is formed by the PECVD method, for example.

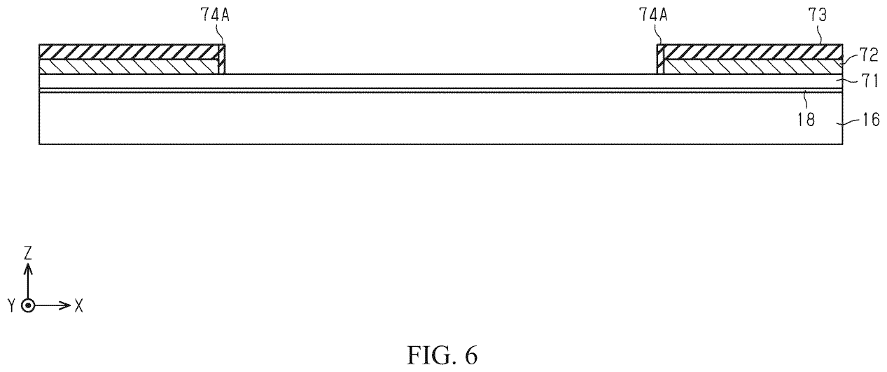

Next, as shown in FIG. 6, the second protective layer 74 is etched back by, for example, the full-surface anisotropic dry etching until the upper surface of the first electrode layer 72 is exposed. As a result, the remaining portion of the second protective layer 74 is formed as a mask 74A covering the side surface of the first electrode layer 72, the side surface of the first protective layer 73 and a portion of the upper surface of the first nitride semiconductor layer 71.

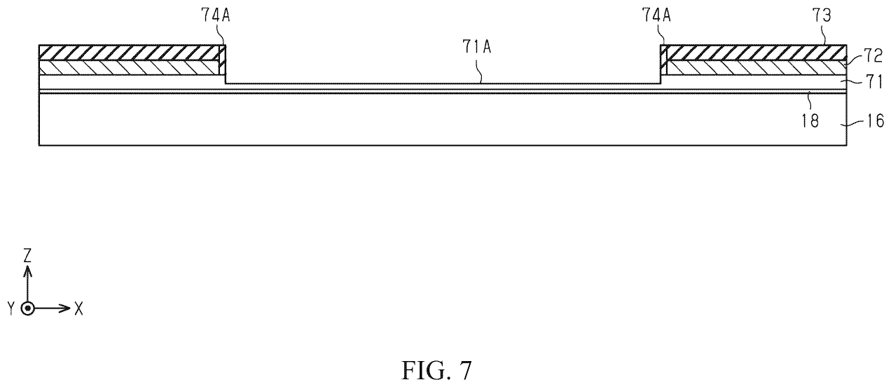

Next, as shown in FIG. 7, etching is performed using the first protective layer 73 and the mask 74A, thereby selectively removing the first nitride semiconductor layer 71. Therefore, the drain portion 71A is formed to be locally thinner than the first nitride semiconductor layer 71. The drain portion 71A is a portion for forming the drain-side extension portion 46.

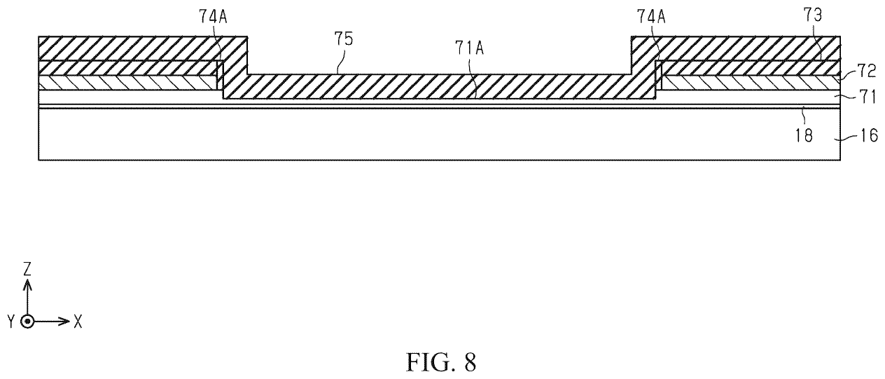

Next, as shown in FIG. 8, a third protective layer 75 is formed to cover the first protective layer 73, the mask 74A, and the drain portion 71A of the first nitride semiconductor layer 71. The third protective layer 75 is, for example, a SiN layer. The third protective layer 75 is formed by the PECVD method, for example.

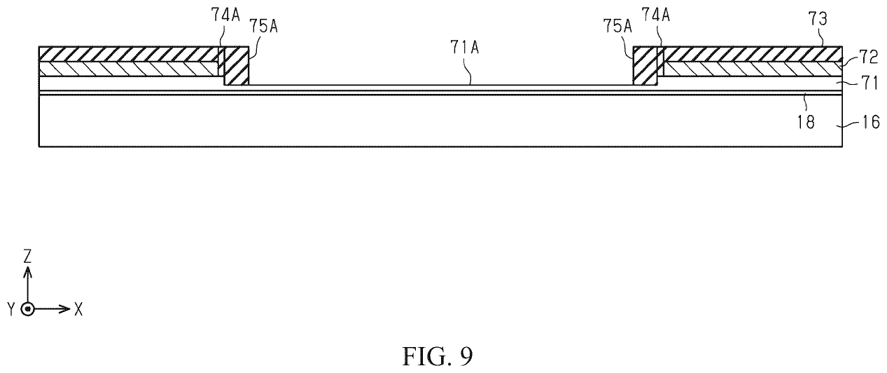

Next, as shown in FIG. 9, the third protective layer 75 is etched back by, for example, the full-surface anisotropic dry etching until the upper surface of the drain portion 71A of the first nitride semiconductor layer 71 is exposed. As a result, the remaining portion of the third protective layer 75 is formed into the mask 75A covering the side surface of the mask 74A, the side surface of the first nitride semiconductor layer 71 and a portion of the upper surface of the drain portion 71A.

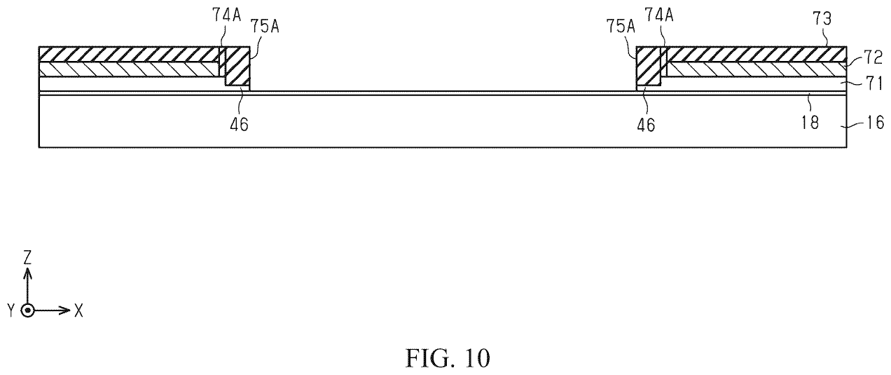

Next, as shown in FIG. 10, the drain portion 71A of the first nitride semiconductor layer 71 is selectively removed by etching using the first protective layer 73, the mask 74A, and the mask 75A. Therefore, the remaining portion of the drain portion 71A is formed as the drain-side extension portion 46.

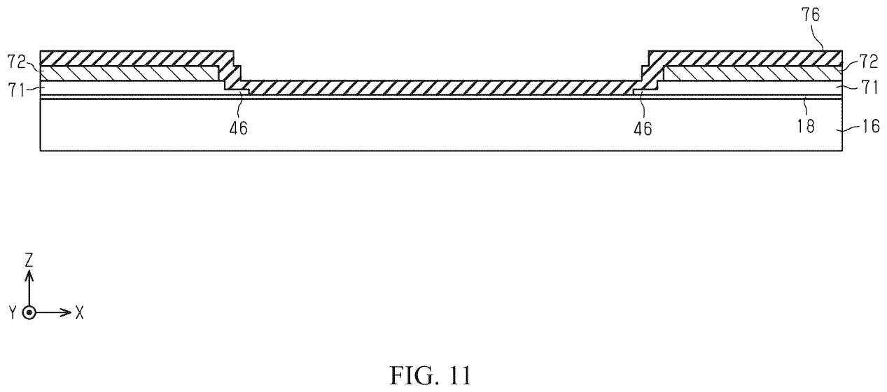

Next, as shown in FIG. 11, after peeling off the first protective layer 73, the mask 74A and the mask 75A, a first insulator layer 76 covering the first electrode layer 72, the first nitride semiconductor layer 71 and the electron supply layer 18 is formed. The first insulator layer 76 is a layer for forming the first passivation layer 51. The first insulator layer 76 is, for example, a SiN layer. The first insulator layer 76 is formed by, for example, the Low Pressure Chemical Vapor Deposition (LPCVD) method.

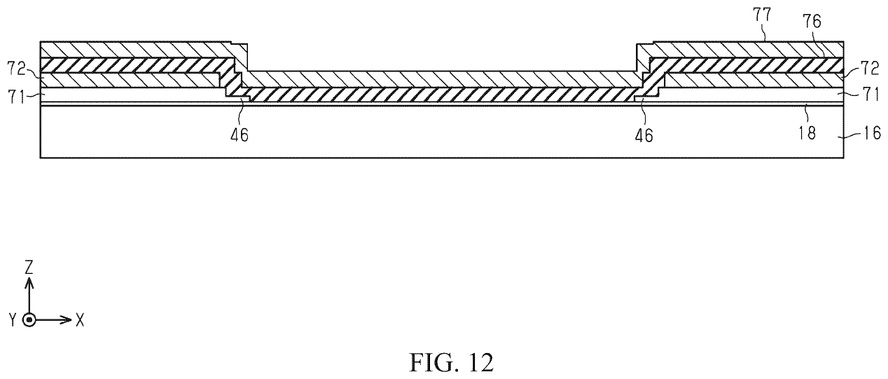

Next, as shown in FIG. 12, a second electrode layer 77 is formed on the first insulator layer 76. The second electrode layer 77 is a layer used to form the field plate electrode 53, and is, for example, a TiN layer. The second electrode layer 77 is formed by the PECVD method, for example.

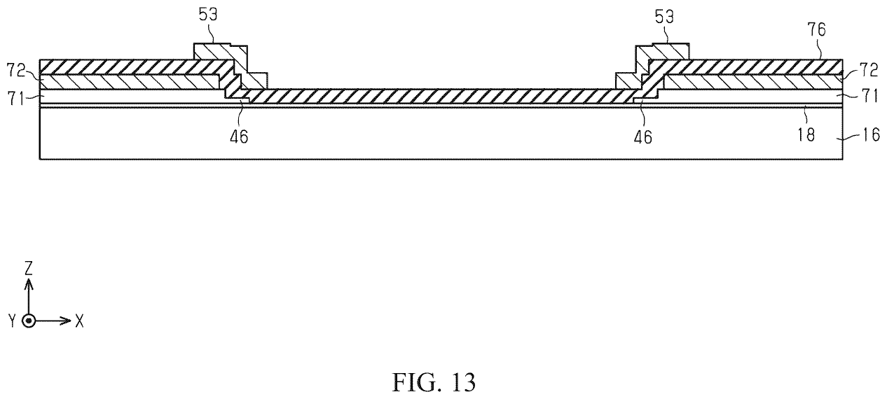

Next, as shown in FIG. 13, the second electrode layer 77 is selectively removed. As a result, the remaining portion of the second electrode layer 77 is formed into the field plate electrode 53. The second electrode layer 77 is selectively removed by, for example, performing photolithography and etching using a mask.

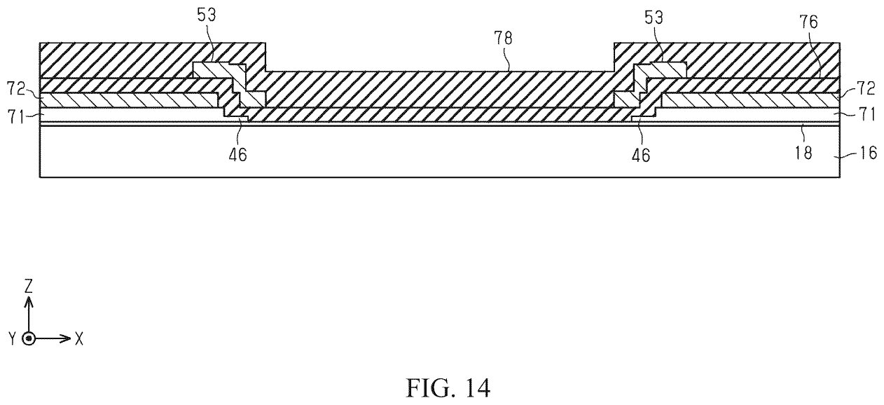

Next, as shown in FIG. 14, a second insulator layer 78 covering the first insulator layer 76 and the field plate electrode 53 is formed. The second insulator layer 78 is a layer for forming the second passivation layer 52. The second insulator layer 78 is, for example, a SiO₂ layer. The second insulator layer 78 is formed by, for example, the PECVD method.

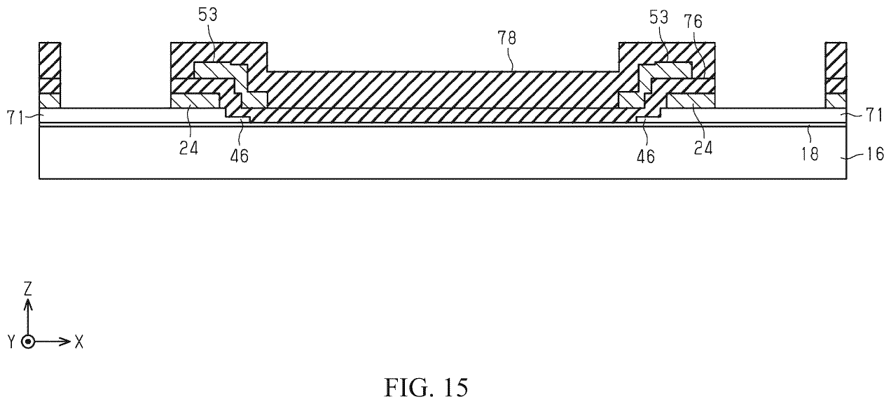

Next, as shown in FIG. 15, the first electrode layer 72, the first insulator layer 76 and the second insulator layer 78 are selectively removed so as to expose a portion of the upper surface of the first nitride semiconductor layer 71. The first electrode layer 72, the first insulator layer 76, and the second insulator layer 78 are selectively removed by, for example, performing photolithography and etching using a mask. As a result, the remaining portion of the first electrode layer 72 is formed into the gate electrode 24.

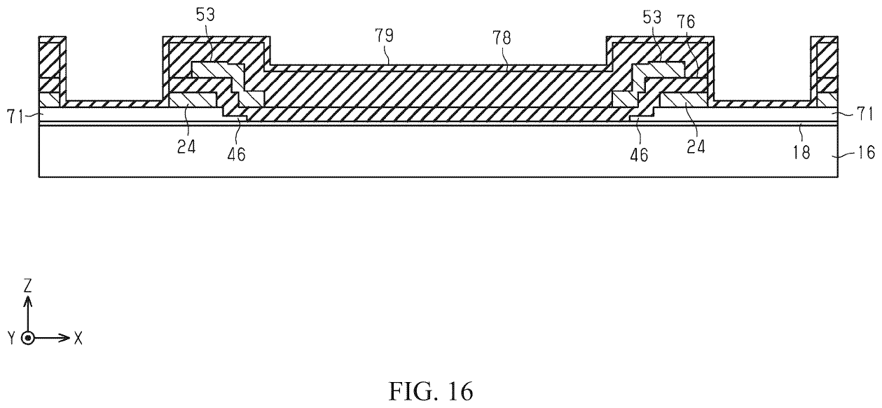

Next, as shown in FIG. 16, a third insulator layer 79 covering the first nitride semiconductor layer 71, the first electrode layer 72, the first insulator layer 76 and the second insulator layer 78 is formed. The third insulator layer 79 is, for example, a SiN layer. The third insulator layer 79 is formed by the PECVD method, for example.

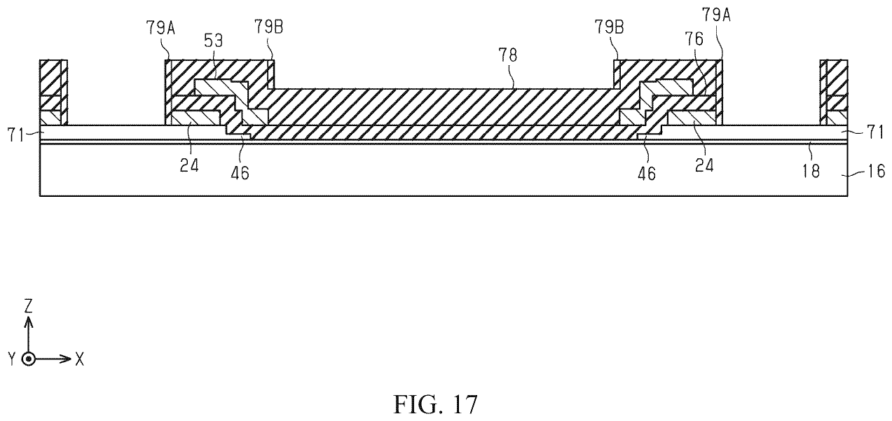

Next, as shown in FIG. 17, the third insulator layer 79 is etched back by, for example, full-surface anisotropic dry etching until the upper surface of the first nitride semiconductor layer 71 is exposed. As a result, the remaining portions of the third insulator layer 79 form the second passivation component parts 79A and 79B. The second passivation component part 79A covers the side surface of the gate electrode 24, the side surface of the second insulator layer 78 located above the side surface of the gate electrode 24, and a portion of the upper surface of the first nitride semiconductor layer 71. The second passivation component part 79B covers a portion of the upper surface and a portion of the side surface of the second insulator layer 78.

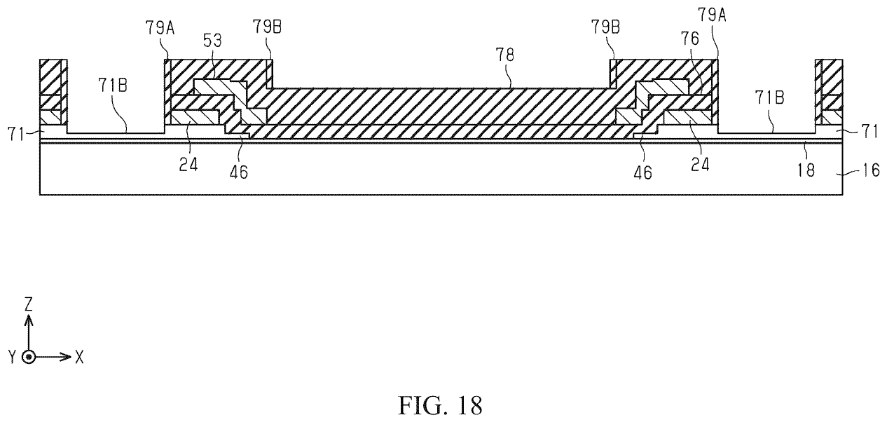

Next, as shown in FIG. 18, the first nitride semiconductor layer 71 is selectively removed by etching using the first protective layer 73 and the second passivation component part 79B. As a result, the source portion 71B is formed that is locally thinner than the first nitride semiconductor layer 71. The source portion 71B is a portion for forming the source-side extension portion 44.

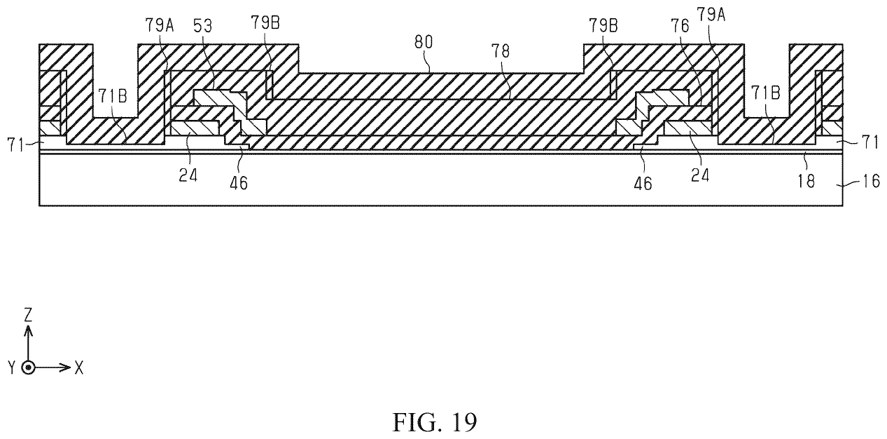

Next, as shown in FIG. 19, a fourth insulator layer 80 covering the source-side extension portion 44 of the first nitride semiconductor layer 71, the second insulator layer 78, and the second passivation component portions 79A and 79B is formed. The fourth insulator layer 80 is, for example, a SiO₂ layer. The fourth insulator layer 80 is formed by, for example, the PECVD method.

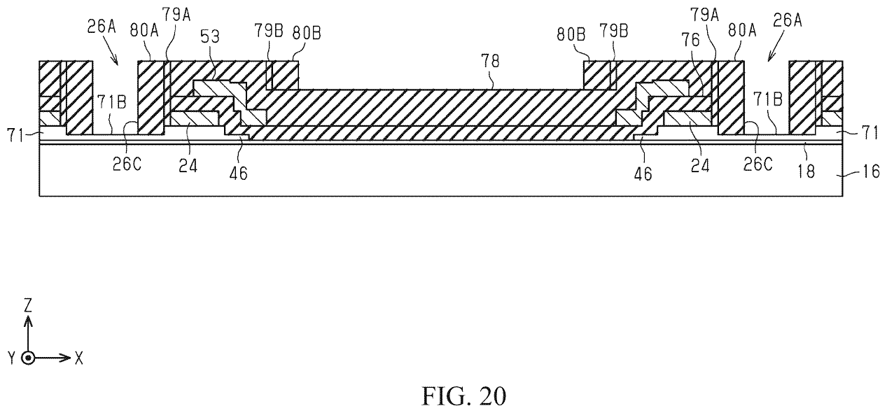

Next, as shown in FIG. 20, the fourth insulator layer 80 is etched back by, for example, full-surface anisotropic dry etching until the upper surface of the source-side extension portion 44 of the first nitride semiconductor layer 71 is exposed. In addition, the remaining portion of the fourth insulator layer 80 is used to form the second passivation component portions 80A and 80B. The second passivation component portion 80A covers the side surface of the second passivation component portion 79A and a portion of the upper surface and side surface of the first nitride semiconductor layer 71. The side surface of the second passivation component portion 80A is the passivation first side surface 26C. The second passivation component portion 80B covers a portion of the side surface of the second passivation component portion 79A and a portion of the upper surface of the second insulator layer 78.

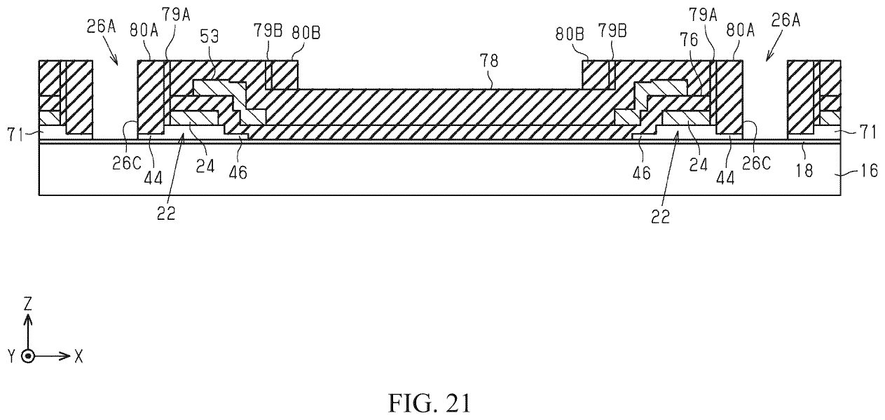

Next, as shown in FIG. 21, the source portion 71B of the first nitride semiconductor layer 71 is selectively removed by etching using the second insulator layer 78 and the second passivation component portions 79A, 79B, 80A, and 80B. Therefore, the remaining portion of the source portion 71B is formed as the source-side extension portion 44. The remaining portion of the first nitride semiconductor layer 71 is used to form the gate layer 22 having the source-side extension portion 44 and the drain-side extension portion 46. In addition, the first opening 26A of the passivation layer 26 is thus formed in such a manner that the gate layer side surface 22C located at the end of the gate layer 22 is exposed.

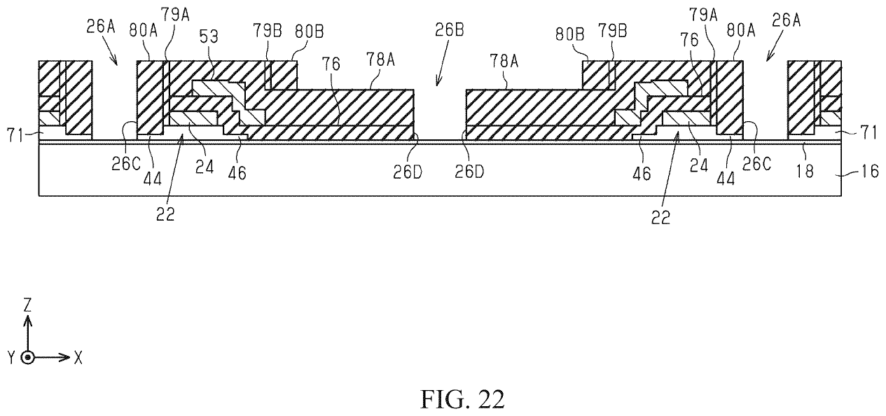

Next, as shown in FIG. 22, the first insulator layer 76 and the second insulator layer 78 are selectively removed so as to expose a portion of the upper surface of the electron supply layer 18. The first insulator layer 76 and the second insulator layer 78 are selectively removed by photolithography and etching using a mask, for example. Thus, the passivation layer 26 and the second opening 26B of the passivation layer 26 are formed.

Specifically, the first passivation layer 51 is formed using the remaining portion of the first insulator layer 76. In addition, the second passivation layer 52 is formed from the remaining portion 78A of the second insulator layer 78 and the second passivation component portions 79A, 79B, 80A, and 80B. The side surface of the first passivation layer 51 where the second opening 26B is formed and the side surface of the second passivation layer 52 (the side surface of the remaining portion 78A of the second insulator layer 78) serve as the passivation second side surface 26D.

The method for manufacturing the nitride semiconductor device 10 further includes the step of forming the source insulator film 61 and the drain insulator film 62 on the passivation first side surface 26C of the passivation layer 26. This step includes forming an insulator layer (the fifth insulator layer 81 described below) covering the upper surface and the passivation first side surface 26C of the passivation layer 26, the side surface of the gate layer 22 on the source electrode 28 side (the side surface of the source-side extension portion 44), and the upper surface of the electron supply layer 18; and removing a portion of the insulator layer covering the upper surface of the electron supply layer 18.

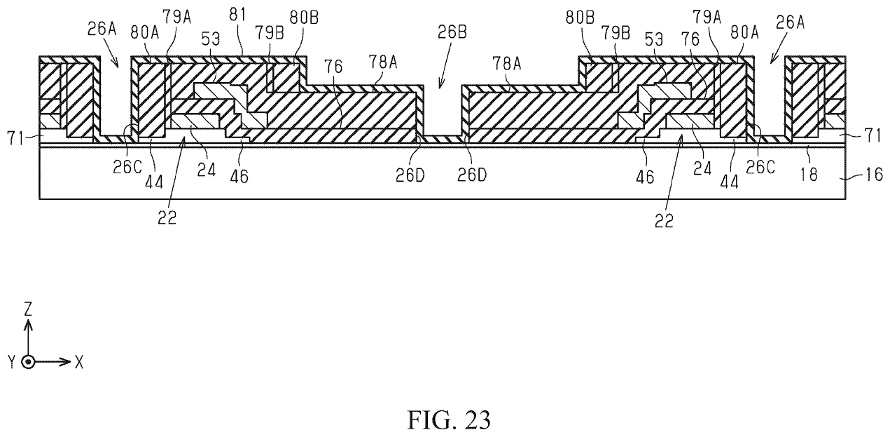

As shown in FIG. 23, a fifth insulator layer 81 is formed to cover the upper surface and side surface of the passivation layer 26, the side surface of the source-side extension portion 44 of the gate layer 22, and the upper surface of the electron supply layer 18 exposed from the first opening 26A and the second opening 26B. The fifth insulator layer 81 is, for example, a SiO₂ layer. The fifth insulator layer 81 is formed by the PECVD method, for example.

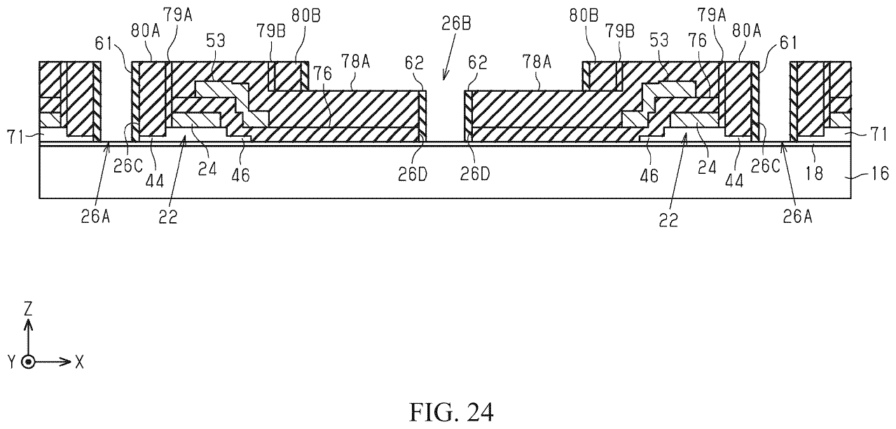

Next, as shown in FIG. 24, the fifth insulator layer 81 is etched back by, for example, full-surface anisotropic dry etching until the upper surface of the electron supply layer 18 is exposed. That is, the portions of the fifth insulator layer 81 formed on the upper surface of the passivation layer 26 and the upper surface of the electron supply layer 18 are removed. As a result, the source insulator film 61 covering the passivation first side surface 26C of the passivation layer 26 is formed, and the drain insulator film 62 covering the passivation second side surface 26D is formed. In this way, the source insulator film 61 and the drain insulator film 62 can be formed by self-alignment.

The method for manufacturing the nitride semiconductor device 10 includes the step of forming the source electrode 28 and the drain electrode 30 so as to be in contact with the electron supply layer 18.

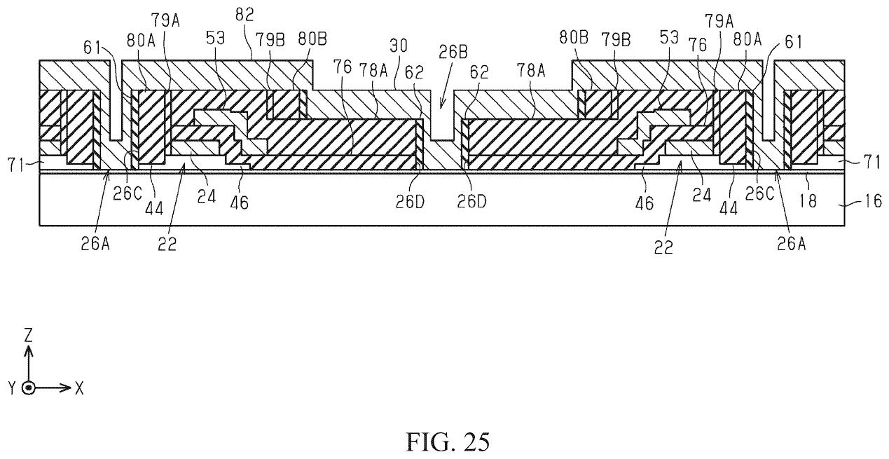

As shown in FIG. 25, the third electrode layer 82 is formed on the passivation layer 26, the source insulator film 61 and the drain insulator film 62. The third electrode layer 82 is a layer used to form the source electrode 28 and the drain electrode 30, and is, for example, a Ti layer. The third electrode layer 82 is formed by the PECVD method, for example.

The third electrode layer 82 is formed on the entire upper surface of the passivation layer 26. The third electrode layer 82 fills the first opening 26A of the passivation layer 26 and is in contact with the upper surface of the electron supply layer 18 and the source insulator film 61 within the first opening 26A. The third electrode layer 82 fills the second opening 26B of the passivation layer 26 and is in contact with the upper surface of the electron supply layer 18 and the drain insulator film 62 within the second opening 26B. In addition, when the third electrode layer 82 is formed, the bonding via 54 electrically connecting the field plate electrode 53 and the third electrode layer 82 is formed in the passivation layer 26.

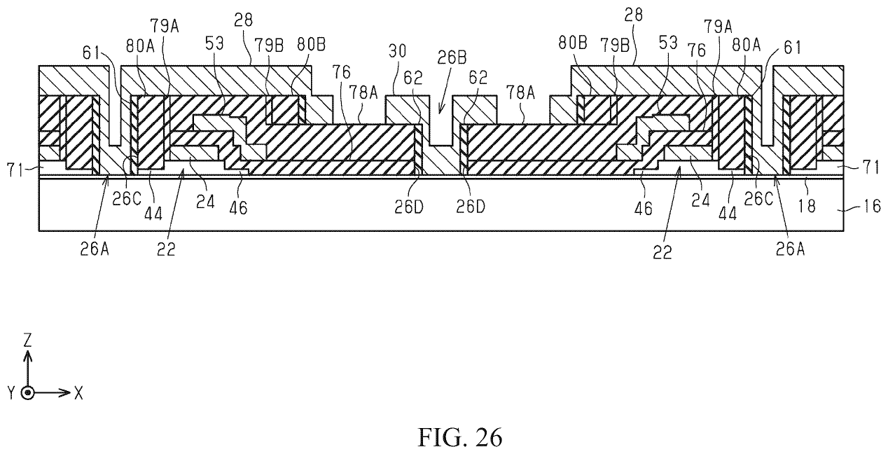

Next, as shown in FIG. 26, the third electrode layer 82 is selectively removed. As a result, the remaining portion of the third electrode layer 82 is formed into the source electrode 28 and the drain electrode 30. The third electrode layer 82 is selectively removed by, for example, performing photolithography and etching using a mask. Through the above steps, the nitride semiconductor device 10 as shown in FIG. 1 is manufactured.

### [Functions]

Next, the function of the nitride semiconductor device 10 according to the embodiment will be described.

As shown in FIG. 3, the source insulator film 61 of the nitride semiconductor device 10 is formed on the passivation first side 26C of the passivation layer 26 and the gate layer side surface 22C (the front end surface of the source-side extension portion 44) of the gate layer 22. The source insulator film 61 is formed in manner of contacting the source electrode 28 and the gate layer side surface 22C.

By disposing the source insulator film 61 between the gate layer 22 and the source electrode 28, the gate layer 22 and the source electrode 28 are effectively separated, such that the gate layer 22 is insulated from the source electrode 28. As a result, the leakage path electrically connecting the gate electrode 24, the gate layer 22, and the source electrode 28 is blocked, thereby suppressing the generation of gate leakage current and improving the gate withstand voltage.

In addition, since the source insulator film 61 is the only component located between the gate layer 22 and the source electrode 28 in the first direction, the source electrode 28 can be disposed at a position closer to the gate layer side surface 22C of the gate layer 22. Therefore, the distance between the source electrode 28 and the drain electrode 30 can be shortened, thereby achieving the reduction of on-resistance.

### Effects

The nitride semiconductor device 10 according to the embodiments can obtain the following effects.

(1-1)

The nitride semiconductor device 10 includes: the electron travelling layer 16; the electron supply layer 18 formed on the electron travelling layer 16; the gate layer 22 formed on the electron supply layer; and the gate electrode 24 formed on the gate layer 22; the source electrode 28 and the drain electrode 30 in contact with the upper surface of the electron supply layer 18; and the passivation layer 26 formed above the electron supply layer 18, the gate layer 22 and the gate electrode 24. The gate layer 22 includes the gate layer side surface 22C, which is located at the end on the source electrode 28 side in the direction in which the gate layer 22, the source electrode 28 and the drain electrode 30 are arranged, i.e. the first direction. The passivation layer 26 includes the passivation first side surface 26C facing the source electrode 28 in the first direction. The nitride semiconductor device 10 further includes the source insulator film 61 that covers the gate layer side surface 22C and the passivation first side surface 26C and insulates the gate layer 22 from the source electrode 28.

According to this configuration, the leakage path electrically connecting the gate electrode 24, the gate layer 22 and the source electrode 28 is blocked by the source insulator film 61. By blocking the leakage path, the generation of the gate leakage current flowing from the gate electrode 24 to the source electrode 28 is suppressed so as to improve the gate withstand voltage. In addition, since the source electrode 28 can be disposed closer to the gate layer side surface 22C of the gate layer 22, the distance between the source electrode 28 and the drain electrode 30 can be shortened, thereby achieving the reduction of the on-resistance. Therefore, not only the gate withstand voltage can be improved, but also the on-resistance can be reduced.

In addition, according to this configuration, the degree of freedom in selecting the material of the passivation layer 26 is improved. For example, a material that can more stably insulate the gate electrode 24 and the source electrode 28 even if the source electrode 28 is sintered is selected as the material constituting the source insulator film 61. In this case, the material of the passivation layer 26 can be selected without considering the insulation between the gate electrode 24 and the source electrode 28 after the sintering process. Further, in one example, the source insulator film 61 is made of a material with higher insulating properties than the portion of the passivation layer 26 forming the passivation first side surface 26C.

(1-2)

The passivation first side surface 26C is located above the gate layer side surface 22C. According to this configuration, the passivation first side surface 26C and the gate layer side surface 22C form one continuous side surface, that is, a side wall. Therefore, the source insulator film 61 can be easily formed by self-alignment with respect to the side wall. In this case, it is easy to shorten the first direction length L3 of the source insulator film 61. Therefore, the effect of significantly reducing the on-resistance will be obtained.

(1-3)

The passivation layer 26 includes a first passivation layer 51 formed on at least a region of the electron supply layer 18 closer to the drain electrode 30 than the gate layer 22, and a second passivation layer 52 formed on the first passivation layer 51.

According to this structure, other structures such as the field plate electrode 53 can be easily arranged between the first passivation layer 51 and the second passivation layer 52. In addition, by making the materials constituting the first passivation layer 51 and the second passivation layer 52 different, the properties of the region formed by the first passivation layer 51 and the region formed by the second passivation layer 52 in the passivation layer 26 can be made different.

(1-4)

The second passivation layer 52 has a source side portion 52A formed on a region of the gate layer 22 closer to the source electrode than the gate electrode 24. The passivation first side surface 26C is the side surface of the end portion of the source-side portion 52A of the second passivation layer 52 located on the source electrode 28 side.

According to this configuration, by adjusting the thickness of the source side portion 52A of the second passivation layer 52, it is easy to form the side wall formed by the passivation first side surface 26C and the gate layer side surface 22C higher. When the source insulator film 61 is formed by self-alignment, since the side walls are formed higher, the source insulator film 61 can be formed with good accuracy with respect to the first direction length L3. Therefore, the effect of being able to reduce the on-resistance more significantly is obtained.

(1-5)

The source side portion 52A of the second passivation layer 52 is thicker than the first passivation layer 51. According to this configuration, the above-mentioned effect (1-4) will be obtained more significantly.

(1-6)

The gate electrode 24 includes an electrode side surface 24A located at the end on the source electrode 28 side in the first direction. The first passivation layer 51 includes a first side surface 51A located at the end on the source electrode 28 side in the first direction. The first side surface 51A of the first passivation layer 51 is located on the electrode side surface 24A of the gate electrode 24. The source side portion 52A of the second passivation layer 52 is in contact with the electrode side surface 24A of the gate electrode 24 and the first side surface 51A of the first passivation layer 51.

The end portion of the junction portion between the gate electrode 24 and the gate layer 22 on the source electrode 28 side is a portion where large electric field concentration is likely to occur. According to the above configuration, the end portion of the junction portion on the source electrode 28 side where large electric field concentration is likely to occur is covered with the second passivation layer 52. Therefore, by forming the second passivation layer 52 with a material suitable for alleviating electric field concentration, there is no need to consider alleviation of the electric field concentration at said portion when selecting the material constituting the first passivation layer 51. Therefore, the degree of freedom in selecting the material of the first passivation layer 51 increases. Furthermore, in one example, the second passivation layer 52 is made of a material that has a higher property of suppressing electric field concentration and relaxation than the material constituting the first passivation layer 51.

(1-7)

The first passivation layer 51 is a SiN layer, and the second passivation layer 52 is a SiO₂ layer. According to this configuration, by setting the first passivation layer 51 as a SiN layer, the surface protecting the electron supply layer 18 is obtained, thereby achieving the effect of reducing the trap energy level. By setting the second passivation layer 52 as a SiO₂ layer, it is easy to ensure the insulation between the gate electrode 24 and the source electrode 28 after the source electrode 28 is sintered.

(1-8)

The field plate electrode 53 is also included. The field plate electrode 53 is formed between the first passivation layer 51 and the second passivation layer 52 and electrically connected to the source electrode 28. At least a portion of the field plate electrode 53 is formed between the gate layer 22 and the drain electrode 30 in the first direction.

According to this configuration, when a high voltage is applied to the drain electrode 30, the field plate electrode 53 extends the depletion layer toward the 2DEG 20 directly below it, thereby achieving the effect of alleviating the electric field concentration in the drain-source region. As a result, the insulation damage to the electron supply layer 18 and the passivation layer 26 caused by local electric field concentration can be suppressed, and the drain-source withstand voltage can be improved.

(1-9)

The source electrode 28 includes a source field plate portion 28B formed on the second passivation layer 52. The end portion 28C of the source field plate portion 28B on the drain electrode 30 side is located closer to the drain electrode 30 than the field plate electrode 53. According to this configuration, when a high voltage is applied to the drain electrode 30, the source field plate portion 28B extends the depletion layer toward the 2DEG 20 directly below it, thereby achieving the effect of alleviating the electric field concentration in the drain-source region. As a result, the insulation damage to of the electron supply layer 18 and the passivation layer 26 caused by local electric field concentration can be suppressed, and the drain-source withstand voltage can be improved.

(1-10)

The gate layer 22 includes a ridge portion 42 that is in contact with the electron supply layer 18; and a source-side extension portion 44 that is in contact with the electron supply layer 18 and extends from the ridge portion 42 toward the source electrode 28 side in the first direction, and is thinner than the ridge portion 42. The gate layer side surface 22C of the gate layer 22 is the front end surface of the source-side extension portion 44. In addition, the gate layer 22 includes a drain-side extension portion 46 that is in contact with the electron supply layer 18 and extends from the ridge portion 42 toward the drain electrode 30 side in the first direction, and is thinner than the ridge portion.

According to these configurations, the source-side extension portion 44 and the drain-side extension portion 46 allow the electric force lines concentrated at the lower end of the ridge portion 42 to escape to the respective extension portions 44 and 46 when the gate is forward biased, thereby making the potential within the gate layer 22 in the first direction become uniform. As a result, the electric field intensity acting on the end portion of the gate electrode 24 can be reduced, thereby suppressing the generation of gate leakage current when a high gate voltage is applied and improving the gate withstand voltage.

(1-11)

The first direction length L3 of the source insulator film 61 is shorter than the first direction length L1 of the source-side extension portion 44. In addition, the first direction length of the source insulator film is less than 100 nm. According to these configurations, by making the first direction length L3 of the source insulator film 61 shorter, the effect of significant reduction of on-resistance can be obtained.

(1-12)

The passivation layer 26 includes the passivation second side surface 26D facing the drain electrode 30 in the first direction. The nitride semiconductor device 10 further includes a drain insulator film that covers the passivation second side surface 26D and insulates the passivation second side surface 26D from the drain electrode 30.

According to this configuration, by interposition at where a relatively large electric field concentration occurs, i.e. between the end portion of the drain electrode 30 in the first direction and the passivation layer 26, the injection of electrons from the drain electrode 30 into the passivation layer 26 can be suppressed. As a result, the long-term stability of the electrical characteristics (for example, drain-source withstand voltage) of the nitride semiconductor device 10 can be achieved.

### Modified Examples

The above-described embodiments can be modified as follows, for example. The above-described embodiments and the following modifications can be combined with each other as long as no technical contradiction occurs. In addition, in the following modified examples, the same reference numerals as those in the above-described embodiments are assigned to the parts that are common to the above-described embodiments, and the relevant description is omitted.
The shape of the gate layer 22 may also be changed. For example, one of the source-side extension portion 44 and the drain-side extension portion 46 may be omitted from the gate layer 22. In addition, the gate layer 22 may have a shape in which the source-side extension portion 44 and the drain-side extension portion 46 are omitted. For example, the gate layer 22 may be formed only of the ridge portion 42.
In the above embodiments, the field plate electrode 53 may also be omitted. In this case, the passivation layer 26 may be composed of one layer.
In the above embodiments, the source electrode 28 may omit the source field plate portion 28B.
In the above embodiments, the number of HEMTs formed in the working region is not particularly limited.

The expression “on” used in the disclosure includes both meanings of “on” and “above” unless the context clearly indicates otherwise. Therefore, the expression “component A is formed on component B” is intended to express that in one embodiment, component A may be directly disposed on component B and in contact with component B, while in another embodiment, component A may be arranged above component B without contacting component B. That is, the expression “on” does not exclude the structure in which other component is formed between component A and component B.

The Z direction used in the disclosure is not necessarily the vertically straight direction, nor does it need to be exactly the same as the vertically straight direction. Therefore, the various structures disclosed herein are not limited to the case where “upper” and “lower” in the Z direction described in this specification are “upper” and “lower” in the vertically straight direction. For example, the X direction may be a vertically straight direction, or the Y direction may be a vertically straight direction.

The words “first”, “second”, “third” and the like in the disclosure are only used to distinguish the objects, and are not intended to rank the objects.

### Note

A method for manufacturing a nitride semiconductor device (10), comprising the following steps:
forming an electron travelling layer (16) made of a nitride semiconductor;
forming an electron supply layer (18) on the electron travelling layer (16) and made of a nitride semiconductor having a band gap larger than a band gap of the electron travelling layer (16);
forming a gate layer (22) on the electron supply layer (18) and made of a nitride semiconductor including acceptor-type impurities;
forming a gate electrode (24) on the gate layer (22);
forming a passivation layer (26) covering the electron supply layer (18), the gate layer (22), and the gate electrode (24) and having a first opening (24A) and a second opening (24B);
forming a source electrode (28) contacting the electron supply layer (18) through the first opening (24A);
forming a drain electrode (30) contacting the electron supply layer (18) through the second opening (24B); and
forming a source insulator film (61) insulating the gate layer (22) from the source electrode (28); wherein
the passivation layer (26) is formed in such a manner that the gate layer side surface (22C) of the gate layer (22) located at the end portion on the first opening (24A) side is exposed from the first opening (24A),
before forming the source electrode (28) and after forming the insulator layer (81) covering the upper surface and side surface of the passivation layer (26), the gate layer side surface (22C) of the gate layer (22), and the upper surface of the electron supply layer (18) exposed from the first opening (24A), the source insulator film (61) is formed by removing the portions of the insulator layer (81) formed on the upper surface of the passivation layer (26) and the upper surface of the electron supply layer (18).

1. A nitride semiconductor device, comprising:
an electron travelling layer, made of a nitride semiconductor;
an electron supply layer, formed on the electron travelling layer and made of a nitride semiconductor having a band gap larger than a band gap of the electron travelling layer;
a gate layer, formed on the electron supply layer and made of a nitride semiconductor including acceptor-type impurities;
a gate electrode, formed on the gate layer; and
a source electrode and a drain electrode, arranged to sandwich the gate layer and in contact with an upper surface of the electron supply layer;
a passivation layer, formed on the electron supply layer, the gate layer and the gate electrode, wherein
when a direction in which the gate layer, the source electrode and the drain electrode are lined up on the upper surface of the electron supply layer is a first direction,
the gate layer includes a gate layer side surface located at an end portion of a side of the source electrode along the first direction, and
the passivation layer includes a passivation first side surface facing the source electrode along the first direction, and
the nitride semiconductor device further comprises a source insulator film covering the gate layer side surface and the passivation first side surface, wherein the source insulator film insulates the gate layer from the source electrode.

2. The nitride semiconductor device of claim 1, wherein the passivation first side surface is located on the gate layer side surface.

3. The nitride semiconductor device of claim 1, wherein the passivation layer includes:
a first passivation layer, at least formed on a region of the electron supply layer and closer to a side of the drain electrode than the gate layer; and
a second passivation layer, formed on the first passivation layer.

4. The nitride semiconductor device of claim 2, wherein the passivation layer includes:
a first passivation layer, at least formed on a region of the electron supply layer and closer to a side of the drain electrode than the gate layer; and
a second passivation layer, formed on the first passivation layer.

5. The nitride semiconductor device of claim 3, wherein
the second passivation layer includes a source side portion formed on a region of the gate layer closer to the source electrode than the gate electrode, and
the passivation first side surface is a side surface located at the end portion of the side of the source electrode on the source side portion of the second passivation layer.

6. The nitride semiconductor device of claim 4, wherein
the second passivation layer includes a source side portion formed on a region of the gate layer closer to the source electrode than the gate electrode, and
the passivation first side surface is a side surface located at the end portion of the side of the source electrode on the source side portion of the second passivation layer.

7. The nitride semiconductor device of claim 5, wherein the source side portion of the second passivation layer is thicker than the first passivation layer.

8. The nitride semiconductor device of claim 5, wherein
the gate electrode includes an electrode side surface located at the end portion of the side of the source electrode along the first direction,
the first passivation layer includes a first side surface located at the end portion of the side of the source electrode along the first direction,
the first side surface of the first passivation layer is located on the electrode side surface of the gate electrode, and
the source side portion of the second passivation layer is in contact with the electrode side surface of the gate electrode and the first side surface of the first passivation layer.

9. The nitride semiconductor device of claim 3, wherein the first passivation layer and the second passivation layer are made of different materials.

10. The nitride semiconductor device of claim 4, wherein the first passivation layer and the second passivation layer are made of different materials.

11. The nitride semiconductor device of claim 9, wherein
the first passivation layer is a SiN layer, and
the second passivation layer is a SiO₂ layer.

12. The nitride semiconductor device of claim 3, further comprising:
a field plate electrode, formed between the first passivation layer and the second passivation layer and electrically connected to the source electrode, wherein
the field plate electrode is at least partially formed between the gate layer and the drain electrode along the first direction.

13. The nitride semiconductor device of claim 12, wherein
the source electrode includes a source field plate portion formed on the second passivation layer, and
an end portion of the side of the drain electrode of the source field plate portion is located closer to the drain electrode than the field plate electrode.

14. The nitride semiconductor device of claim 1, wherein the gate layer includes:
a ridge portion, in contact with the electron supply layer; and
a source side extending portion, thinner than the ridge portion and in contact with the electron supply layer, wherein
the source side extending portion extends from the ridge portion toward the side of the source electrode along the first direction, and
the gate layer side surface of the gate layer is a tip surface of the source side extending portion.

15. The nitride semiconductor device of claim 14, wherein a length of the source insulator film along the first direction is less than a length of the source side extending portion along the first direction.

16. The nitride semiconductor device of claim 15, wherein the length of the source insulator film along the first direction is less than 100 nm.

17. The nitride semiconductor device of claim 14, wherein the gate layer is in contact with the electron supply layer and includes a drain side extending portion thinner than the ridge portion and extending from the ridge portion toward the side of the drain electrode along the first direction.

18. The nitride semiconductor device of claim 1, wherein the source insulator film is made of a material different from a material forming a portion of forming the passivation first side surface of the passivation layer.

19. The nitride semiconductor device of claim 2, wherein the source insulator film is made of a material different from a material forming a portion of forming the passivation first side surface of the passivation layer.

20. The nitride semiconductor device of claim 1, wherein
the passivation layer includes a passivation second side surface facing the drain electrode along the first direction, and
the nitride semiconductor device further comprises a drain insulator film covering the passivation second side surface and insulating the passivation second side surface from the drain electrode.
